(19) United States
(12) Patent Application Publication
(10) Pub. No.: US 2019/0296119 A1
(43) Pub. Date: Sep. 26, 2019

(54) SEMICONDUCTOR DEVICE AND METHOD OF MANUFACTURING SEMICONDUCTOR DEVICE

(71) Applicant: LAPIS SEMICONDUCTOR CO., LTD, Yokohama (JP)

(72) Inventor: Ayami Kasai, Miyagi (JP)

(73) Assignee: LAPIS SEMICONDUCTOR CO., LTD, Yokohama (JP)

(21) Appl. No.: 16/357,338

(22) Filed: Mar. 19, 2019

(30) Foreign Application Priority Data
Mar. 26, 2018 (JP) 2018-058435

(51) Int. Cl. H01L 29/423; H01L 21/762; H01L 29/06; H01L 29/66; H01L 29/10; H01L 29/78

(52) U.S. Cl. CPC H01L 29/42364; H01L 21/76224; H01L 29/7801; H01L 29/66674; H01L 29/1045; H01L 29/0649

(57) ABSTRACT

Provided is a semiconductor device including a semiconductor substrate on which an element region of a semiconductor and an element isolation region including an insulating film are formed, one first diffusion layer and the other first diffusion layer formed in the element region extending away from each other in a first direction, a gate oxide film, a gate electrode, and a second diffusion layer formed in a region including a portion in which the gate oxide film is in contact with the insulating film within a channel region, in which an interval between one first diffusion layer and the other first diffusion layer in a section in the first direction in which the second diffusion layer is included is larger than an interval between one first diffusion layer and the other first diffusion layer in a section in the first direction in which the second diffusion layer is not included.

### CROSS-REFERENCE TO RELATED APPLICATION

This application claims the priority benefit of Japan application serial no. 2018-058435, filed on Mar. 26, 2018. The entirety of each of the above-mentioned patent applications is hereby incorporated by reference herein and made a part of this specification.

### BACKGROUND

### Technical Field

The present disclosure relates to a semiconductor device and a method of manufacturing the semiconductor device.

### Description of Related Art

As an element isolation structure of a semiconductor device, shallow trench isolation (STI) in which a trench is provided in the surface of a silicon substrate and an insulating material such as a silicon oxide material is embedded in the trench has become known.

Further, in such a semiconductor device, a technique of forming a parasitic transistor including a sub-channel having characteristics different from those of an original channel at a boundary portion between an element isolation insulating layer based on STI and a gate oxide film in a silicon substrate (or a well region) is known (refers to, for example, Japanese Unexamined Patent Application Publication No. 2004-288873).

For example, in a process of manufacturing the semiconductor device, a “hollow” may be generated at an end of the top face of the element isolation insulating layer. In this case, the film thickness of the gate oxide film in the vicinity of the element isolation insulating layer may be smaller than that of a channel center portion due to the “hollow”, and thus a threshold voltage of the parasitic transistor formed in a region corresponding to the gate oxide film having a small film thickness becomes lower than a threshold voltage of an original transistor.

Thereby, the parasitic transistor is first set to be in an on state with an increase in a gate voltage, and the original transistor is set to be in an on state with a further increase in a gate voltage. Therefore, a so-called hump occurs in which a drain current corresponding to the parasitic transistor flows between a source and a drain in a case where a gate voltage is equal to or greater than the threshold voltage of the parasitic transistor and is lower than the threshold voltage of the original transistor, and a drain current corresponding to the parasitic transistor and the original transistor flows between a source and a drain when the gate voltage is set to be equal to or greater than the threshold voltage of the original transistor.

Such hump characteristics are different from required characteristics, which results in a reduction in an operation margin.

Consequently, a technique has been proposed in which the suppression of hump characteristics is achieved by implanting impurities into a region for forming a parasitic transistor to increase a threshold voltage of a parasitic transistor until the threshold voltage of the parasitic transistor becomes equal to a threshold voltage of an original transistor (refers to, for example, Japanese Unexamined Patent Application Publication No. 2011-176115).

### PATENT DOCUMENTS

[Patent Document 1] Japanese Unexamined Patent Application Publication No. 2004-288873 [Patent Document 2] Japanese Unexamined Patent Application Publication No.

2011-176115

### SUMMARY

Incidentally, for example, a high breakdown voltage transistor dealing with a voltage higher than a power supply voltage for a logic circuit is used at an output stage of a driver driving a liquid crystal display panel. In the high breakdown voltage transistor, a film thickness of a gate oxide film is larger than that of a low breakdown voltage transistor, and the range of a gate voltage causing a hump is increased in gate voltage and drain current characteristics (also referred to as Vg-Id characteristics).

Consequently, also for such a high breakdown voltage transistor, suppressing a hump by implanting impurities into a region where a parasitic transistor is formed (hereinafter, referred to as a hump suppression ion implantation region) has been considered, similar to Japanese Unexamined Patent Application Publication No. 2004-288873 described above.

However, when a high voltage is applied to a gate of the high breakdown voltage transistor, there is a problem in that extension of a depletion layer from a low concentration diffusion layer serving as a source or a drain is suppressed by the hump suppression ion implantation region and a breakdown voltage is reduced.

In addition, increasing a distance between the low concentration diffusion layer and the hump suppression ion implantation region in order to avoid the reduction in the breakdown voltage has been considered, but this correspondingly increases a gate length, which results in a problem that the driving capability of the transistor is reduced.

Consequently, the present disclosure provides a semiconductor device and a method of manufacturing the semiconductor device which are capable of suppressing a hump in gate voltage and drain current characteristics without causing reductions in a breakdown voltage and a driving capability.

According to an aspect of the present disclosure, there is provided a semiconductor device including a semiconductor substrate on which an element region of a semiconductor and an element isolation region surrounding the element region and including an insulating film which is in contact with the element region are formed, one first diffusion layer and another first diffusion layer which are formed in an upper portion in the element region to extend away from each other in a first direction and are configured such that ends thereof in the first direction are in contact with the insulating film, a gate oxide film which is formed on the element region to extend in the first direction and is configured such that an end thereof in the first direction is in contact with the insulating film, a gate electrode which extends in the first direction on the gate oxide film and is configured such that an end thereof in the first direction is formed on the insulating film, and a second diffusion layer which is formed in a region including a portion in which the gate oxide film is in contact with the insulating film within a channel region between the one first diffusion layer and the other first diffusion layer, in which an interval between the one first diffusion layer and the other first diffusion layer in a section in the first direction in which the second diffusion layer is included between the one first diffusion layer and the other first diffusion layer is larger than an interval between the one first diffusion layer and the other first diffusion layer in a section in the first direction in which the second diffusion layer is not included.

According to another aspect of the present disclosure, there is provided a semiconductor device including a semiconductor substrate which includes an element region and an element isolation region surrounding the element region in contact with the element region on a principal surface thereof, an electrode which is configured such that an end thereof is disposed on the element isolation region and is disposed in the element region on the principal surface with an insulating layer interposed therebetween, a pair of first diffusion layers which are disposed opposite to each other in the element region included in a region corresponding to the electrode when seen in a plan view, and a second diffusion layer which is in contact with a side on which a boundary between the element region and the element isolation region is formed and is disposed away from the pair of first diffusion layers in the element region included in the region corresponding to the electrode when seen in a plan view, in which a channel region interposed between the pair of first diffusion layers extends in a direction perpendicular to the side and includes the first diffusion layer, and the channel region includes a first region including the second diffusion layer and configured such that a width in a direction parallel to the side is a first length, and a second region configured such that a width in a direction parallel to the side is a second length shorter than the first length.

According to still another aspect of the present disclosure, a method of manufacturing a semiconductor device that includes an element region of a semiconductor and an element isolation region surrounding the element region and including an insulating film which is in contact with the element region is provided. The method including a first step of implanting impurities into an upper portion in the element region to form one first diffusion layer and another first diffusion layer which extend away from each other in a first direction and are configured such that ends thereof in the first direction are in contact with the insulating film, a second step of implanting impurities into a region including a portion which is in contact with the insulating film in an upper portion in a channel region interposed between the one first diffusion layer and the other first diffusion layer to form a second diffusion layer, and a third step of forming a gate oxide film which extends in the first direction on the element region and is configured such that an end thereof in the first direction is in contact with the insulating film, and a gate electrode which extends in the first direction on the gate oxide film and is configured such that an end thereof in the first direction is disposed on the insulating film, in which the first step includes forming the one first diffusion layer and the other first diffusion layer in the upper portion in the element region, the first diffusion layers being configured such that an interval between the one first diffusion layer and the other first diffusion layer in a section in the first direction in which the second diffusion layer is included between the one first diffusion layer and the other first diffusion layer becomes larger than an interval between the one first diffusion layer and the other first diffusion layer in a section in the first direction in which the second diffusion layer is not included.

### BRIEF DESCRIPTION OF THE DRAWINGS

FIG. 1A is a top view showing the top face of a semiconductor device 100.

FIG. 1B is a cross-sectional view showing a cross-section along line X-X in FIG. 1A.

FIG. 1C is a cross-sectional view showing a cross-section along line Y-Y in FIG. 1A.

FIG. 2 is a top view showing the top face of the semiconductor device 100 according to another example.

FIG. 3 is a top view showing a modification example of the semiconductor device 100 shown in FIG. 2.

FIG. 4 is a flow diagram showing a manufacturing procedure of the semiconductor device 100.

FIG. 5 is a flow diagram showing a manufacturing procedure of the semiconductor device 100.

FIG. 6A is a top view showing the top face of a semiconductor wafer in an initial manufacturing stage.

FIG. 6B is a cross-sectional view showing a cross-section along line X-X in FIG. 6A.

FIG. 6C is a cross-sectional view showing a cross-section along line Y-Y in FIG. 6A.

FIG. 7A is a top view showing the top face of the semiconductor wafer in a low concentration diffusion layer exposure step S1.

FIG. 7B is a step cross-sectional view showing a cross-section along line X-X in FIG. 7A.

FIG. 7C is a step cross-sectional view showing a cross-section along line Y-Y in FIG. 7A.

FIG. 8A is a top view showing the top face of the semiconductor wafer in a low concentration impurity implantation step S2.

FIG. 8B is a step cross-sectional view showing a cross-section along line X-X in FIG. 8A.

FIG. 8C is a step cross-sectional view showing a cross-section along line Y-Y in FIG. 8A.

FIG. 9A is a top view showing the top face of the semiconductor wafer in a hump suppression diffusion region exposure step S3.

FIG. 9B is a step cross-sectional view showing a cross-section along line X-X in FIG. 9A.

FIG. 9C is a step cross-sectional view showing a cross-section along line Y-Y in FIG. 9A.

FIG. 10A is a top view showing the top face of the semiconductor wafer in a hump suppression diffusion region impurity implantation step S4.

FIG. 10B is a step cross-sectional view showing a cross-section along line X-X in FIG. 10A.

FIG. 10C is a step cross-sectional view showing a cross-section along line Y-Y in FIG. 10A.

FIG. 11A is a top view showing the top face of the semiconductor wafer in a polysilicon formation step S5.

FIG. 11B is a step cross-sectional view showing a cross-section along line X-X in FIG. 11A.

FIG. 11C is a step cross-sectional view showing a cross-section along line Y-Y in FIG. 11A.

FIG. 12A is a top view showing the top face of the semiconductor wafer in a gate formation step S6.

FIG. 12B is a step cross-sectional view showing a cross-section along line X-X in FIG. 12A.

FIG. 12C is a step cross-sectional view showing a cross-section along line Y-Y in FIG. 12A.

FIG. 12D is a top view showing another example of the top face of the semiconductor wafer in the gate formation step S6.

FIG. 13A is a top view showing the top face of the semiconductor wafer in a resist removal step S7.

FIG. 13B is a step cross-sectional view showing a cross-section along line X-X in FIG. 13A.

FIG. 13C is a step cross-sectional view showing a cross-section along line Y-Y in FIG. 13A.

FIG. 14A is a top view showing the top face of the semiconductor wafer in a side wall insulating layer formation step S8.

FIG. 14B is a step cross-sectional view showing a cross-section along line X-X in FIG. 14A.

FIG. 14C is a step cross-sectional view showing a cross-section along line Y-Y in FIG. 14A.

FIG. 15A is a top view showing the top face of the semiconductor wafer in a side wall formation step S9.

FIG. 15B is a step cross-sectional view showing a cross-section along line X-X in FIG. 15A.

FIG. 15C is a step cross-sectional view showing a cross-section along line Y-Y in FIG. 15A.

FIG. 16A is a top view showing the top face of the semiconductor wafer in a high concentration diffusion layer formation step S10.

FIG. 16B is a step cross-sectional view showing a cross-section along line X-X in FIG. 16A.

FIG. 16C is a step cross-sectional view showing a cross-section along line Y-Y in FIG. 16A.

FIG. 16D is a top view showing another example of the top face of the semiconductor wafer in the high concentration diffusion layer formation step S10.

FIG. 17A is a top view showing the top face of the semiconductor wafer in a salicide layer formation step S11.

FIG. 17B is a step cross-sectional view showing a cross-section along line X-X in FIG. 17A.

FIG. 17C is a step cross-sectional view showing a cross-section along line Y-Y in FIG. 17A.

FIG. 18A is a top view showing the top face of the semiconductor wafer in an insulating layer formation step S12, a contact formation step S13, and a metal wiring layer formation step S14.

FIG. 18B is a step cross-sectional view showing a cross-section along line X-X in FIG. 18A.

FIG. 18C is a step cross-sectional view showing a cross-section along line Y-Y in FIG. 18A.

### DESCRIPTION OF THE EMBODIMENTS

In the present disclosure, a second diffusion layer which is a hump suppression diffusion region suppressing a hump occurring in gate voltage and drain current characteristics is provided within a channel region between one first diffusion layer and another first diffusion layer. Here, an interval between the one first diffusion layer and the other first diffusion layer in a section including the hump suppression diffusion region between the one first diffusion layer and the other first diffusion layer is made larger than an interval between the one first diffusion layer and the other first diffusion layer in a section not including the hump suppression diffusion region.

With such a configuration, a depletion layer extends from the one first diffusion layer and the other first diffusion layer without suppressing the extension of the depletion layer by the hump suppression diffusion region, and thus it is possible to prevent a breakdown voltage of a transistor from being reduced.

Further, an interval between the one first diffusion layer and the other first diffusion layer is made smaller than an interval therebetween in a section including the hump suppression diffusion region, and thus it is possible to reduce a channel length of the transistor regardless of the size of the hump suppression diffusion region.

Therefore, according to the present disclosure, it is possible to suppress a hump in gate voltage and drain current characteristics without causing reductions in a breakdown voltage and a driving capability.

Hereinafter, an example of the present disclosure will be described in detail.

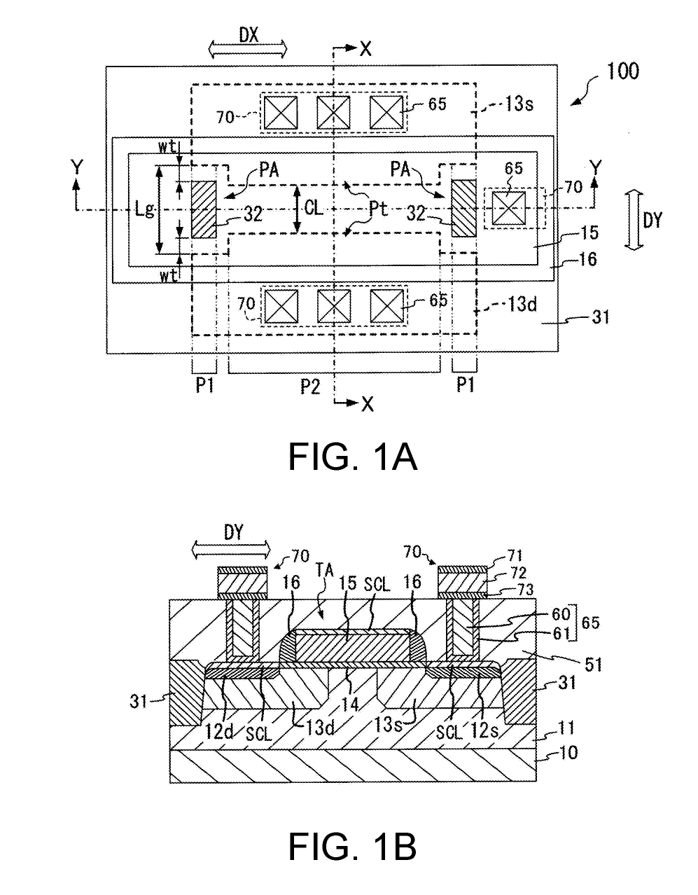

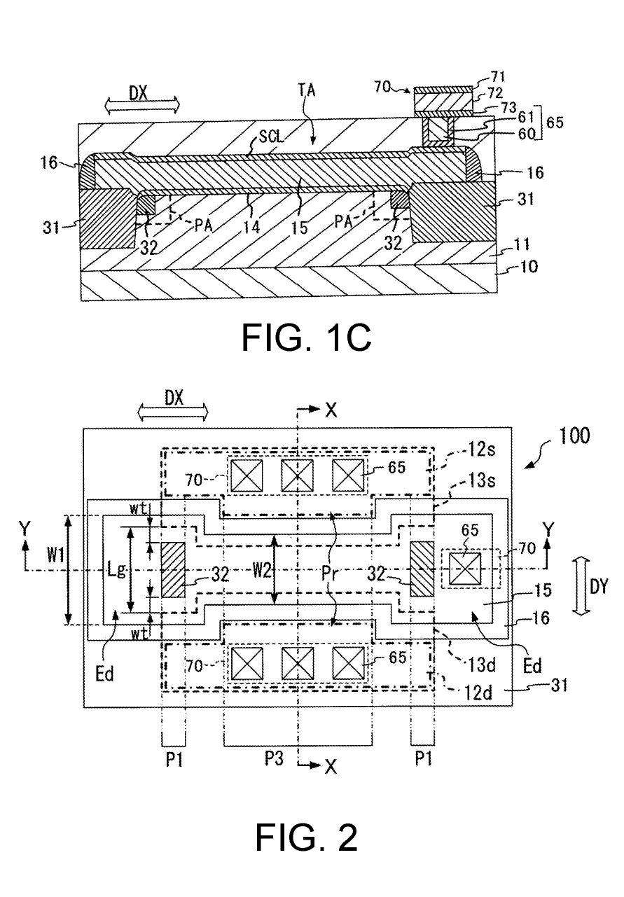

FIG. 1A is a top view of a portion of a semiconductor device 100 according to the present disclosure when seen from above an element formation surface. FIG. 1B is a cross-sectional view along line X-X in FIG. 1A. In addition, FIG. 1C is a cross-sectional view along line Y-Y in FIG. 1A.

As shown in FIG. 1B or 1C, a well 11 of a first conductive type (for example, a p-type conductive type) and an element isolation region in which an element isolation insulating film 31 is embedded in a trench formed in the surface of a semiconductor substrate 10 are formed on the semiconductor substrate 10 formed of silicon (Si) of the first conductive type. In addition, a transistor TA is provided in an element region of the semiconductor substrate 10 defined by the element isolation region, and an insulating layer 51 is provided on the transistor TA.

The transistor TA includes a gate oxide film 14 provided on the semiconductor substrate 10, a gate electrode 15 provided on the gate oxide film 14, and a side wall 16 provided on a side wall of the gate electrode 15. In addition, low concentration diffusion layers 13d and 13s of a second conductive type (for example, an n-type conductive type) which are provided opposite to each other below the gate electrode 15 and a hump suppression diffusion region 32 of a first conductive type which is provided in contact with the element isolation insulating film 31 and away from the low concentration diffusion layers 13d and 13s are provided on the semiconductor substrate 10 below the gate electrode 15.

An element isolation region adopting an STI structure which surrounds the element region is formed on the semiconductor substrate 10. The element isolation region includes a trench surrounding the regions in which the low concentration diffusion layers 13d and 13s are formed and the element isolation insulating film 31, including, for example, a silicon oxide, which is embedded in the trench.

The gate oxide film 14 formed of, for example, a silicon oxide and the gate electrode 15 formed on the top face of the gate oxide film 14 are provided on the semiconductor substrate 10. As shown in FIG. 1C, the gate oxide film 14 is formed on the top face of the well 11 to extend in a direction DX. An end of the gate oxide film 14 in the direction DX is in contact with the element isolation insulating film 31. In addition, the gate electrode 15 is formed on the gate oxide film 14 to extend in the direction DX, and an end thereof in the direction DX is formed on the element isolation insulating film 31. The side wall of the gate electrode 15 is covered with the side wall 16 constituted by an insulating film such as a silicon oxide film, as shown in FIGS. 1B and 1C.

In addition, a low concentration diffusion layer 13d of a second conductive type which serves as a drain of a transistor and a low concentration diffusion layer 13s of a second conductive type which serves as a source of a transistor are formed in the surface layer of the semiconductor substrate 10 in the element formation region, as shown in FIG. 1B. The low concentration diffusion layers 13d and 13s are formed opposite to and away from each other on the semiconductor substrate 10 provided below the gate electrode, and a region interposed between the low concentration diffusion layer 13d and the low concentration diffusion layer 13s of the semiconductor substrate 10 serves as a channel region of the transistor TA.

The low concentration diffusion layers 13s and 13d are formed in the surface layer in the element formation region to extend away from each other in the direction DX shown in FIG. 1A, and ends of the respective low concentration diffusion layers 13s and 13d in the direction DX are in contact with the element isolation insulating film 31 as shown in FIG. 1B.

Each of the low concentration diffusion layers 13d and 13s contains, for example, phosphorus (P⁺) or arsenic (As⁺) of a low concentration n-type conductive type as impurities.

Here, as described above, in the gate oxide film 14 formed in the channel region of the transistor TA, the film thickness of the gate oxide film 14 at a boundary portion between the element isolation insulating film 31 and the gate oxide film 14 is smaller than the film thickness of the gate oxide film 14 in a channel center portion. Accordingly, a parasitic transistor is formed in a region PA including a portion where an end of the gate oxide film 14 and the element isolation insulating film 31 are in contact with each other as shown in FIG. 1C within the channel region between the low concentration diffusion layers 13d and 13s shown in FIG. 1A. Since a threshold voltage of the parasitic transistor is lower than a threshold voltage of an original transistor, a hump occurs in Vg-Id characteristics accordingly.

Consequently, in order to make the threshold voltage of the parasitic transistor equal to or higher than the threshold voltage of the original transistor by increasing the threshold voltage of the parasitic transistor, the hump suppression diffusion region 32 of a first conductive type is formed in the region PA shown in FIG. 1A or 1C. The hump suppression diffusion region 32 contains, for example, boron (B⁺) of a p-type conductive type as impurities. The hump suppression diffusion region 32 is formed in a region including a portion in which the gate oxide film 14 is in contact with the element isolation insulating film 31 as shown in FIG. 1C within the channel region between the low concentration diffusion layer 13d and the low concentration diffusion layer 13s. In addition, the hump suppression diffusion region 32 contains impurities having a higher concentration than those of the channel region of the transistor TA in order to make the threshold voltage of the parasitic transistor equal to the threshold voltage of the original transistor.

Incidentally, when a high voltage is applied to the gate of the transistor, the extension of a depletion layer from the low concentration diffusion layers 13d and 13s serving as a source and a drain is interrupted by the hump suppression diffusion region 32, which may result in a reduction in a breakdown voltage of the transistor.

Consequently, the hump suppression diffusion region 32 is formed at a position away from each of the low concentration diffusion layers 13d and 13s by a predetermined interval wt in a direction DY perpendicular to the direction DX as shown in FIG. 1A so that the depletion layer does not extend without excess and insufficiency from the low concentration diffusion layers 13d and 13s.

That is, an interval between the low concentration diffusion layer 13d and the low concentration diffusion layer 13s in the direction DY is set to be an interval obtained by adding 2·wt to the length of the hump suppression diffusion region 32 in the direction DY, that is, an interval Lg shown in FIG. 1A.

That is, in a section P1 in the first direction DX in which the hump suppression diffusion region 32 is included between the low concentration diffusion layers 13d and 13s, a reduction in a breakdown voltage of the transistor is suppressed by setting an interval between the low concentration diffusion layers 13d and 13s to be the interval Lg shown in FIG. 1A.

Incidentally, when the interval between the low concentration diffusion layers 13d and 13s is uniformly set to be the interval Lg in a case where the length of the hump suppression diffusion region 32 in the direction DY or the interval wt for avoiding a reduction in a breakdown voltage is increased, a gate length is increased, which results in a reduction in a current driving capability of the transistor.

Consequently, as shown in FIG. 1A, the interval Lg between the low concentration diffusion layers 13d and 13s in the section P1 in which the hump suppression diffusion region 32 is included between the low concentration diffusion layers 13d and 13s is made larger than an interval CL between the low concentration diffusion layers 13d and 13s in a section P2 in which the hump suppression diffusion region 32 is not included between the low concentration diffusion layers 13d and 13s.

That is, in the section P2 in which the hump suppression diffusion region 32 is not included between the low concentration diffusion layers 13d and 13s, the interval between the low concentration diffusion layers 13d and 13s is made smaller than the interval therebetween in the section P1 in which the hump suppression diffusion region 32 is included.

Thereby, since the channel length of the transistor can be made short regardless of the length of the hump suppression diffusion region 32 in the direction DY and the interval wt for avoiding a reduction in a breakdown voltage, it is possible to suppress a reduction in the current driving capability of the transistor.

In the surface layers of the low concentration diffusion layer 13d and the low concentration diffusion layer 13s which are defined by the element isolation region and the side wall 16, a high concentration diffusion layer 12d of a second conductive type (for example, an n-type conductive type) and a high concentration diffusion layer 12s of the second conductive type which are respectively included in the low concentration diffusion layer 13d and the low concentration diffusion layer 13s are formed away from each other as shown in FIG. 1B. Each of the high concentration diffusion layers 12d and 12s contains, for example, phosphorus (P⁺) or arsenic (As⁺) of an n-type conductive type as impurities.

The top face of each of the gate electrode 15 and the high concentration diffusion layer 12s and 12d is silicided in order to reduce bonding resistance against a contact to be described later. That is, a salicide (self aligned silicide) layer SCL is formed on the top face of each of the gate electrode 15 and the high concentration diffusion layer 12s and 12d.

As shown in FIGS. 1B and 1C, the salicide layer SCL formed on the top face of each of the high concentration diffusion layers 12d and 12s and the gate electrode 15 and the top faces of the side wall 16 and the element isolation insulating film 31 are covered with the insulating layer 51 including, for example, a silicon oxide.

Each of the high concentration diffusion layers 12d and 12s is coupled with a metal wiring layer 70 formed on the top face of the insulating layer 51 through a contact 65 passing through the insulating layer 51 as shown in FIG. 1B. The gate electrode 15 is coupled to the metal wiring layer 70 formed on the top face of the insulating layer 51 through the contact 65 passing through the insulating layer 51 as shown in FIG. 1C.

In addition, the contact 65 includes a metal plug 60 and a barrier metal 61 covering the surface of the metal plug. The contact 65 is coupled to the metal wiring layer 70 formed on the top face of the insulating layer 51. In addition, the metal wiring layer 70 has a stacked structure constituted by an upper layer barrier metal layer 71, a conductive member 72 formed of an alloy such as aluminum (Al)-copper (Cu), and a lower layer barrier metal 73 formed of, for example, titanium (Ti) or titanium nitride (TiN).

In this manner, in the semiconductor device 100, the convex-shaped low concentration diffusion layers 13d and 13s, which have a protrusion portion Pt protruding in the direction of the channel region throughout the section P2 in which the hump suppression diffusion region 32 is not included between the low concentration diffusion layers 13d and 13s as shown in FIG. 1A, are adopted. Thereby, it is possible to suppress a hump in Vg-Id characteristics without causing reductions in a breakdown voltage and a driving capability.

Further, in the above-described example, layers having a convex shape as shown in FIG. 1A are adopted as the low concentration diffusion layers 13d and 13s, but layers having the same convex shape may be adopted as the high concentration diffusion layers 12d and 12s.

FIG. 2 is a top view when a portion of the semiconductor device 100 according to another example conceived in view of such points is seen from above an element formation surface. Further, in a configuration shown in FIG. 2, configurations other than the shapes of the high concentration diffusion layers 12d and 12s, the gate electrode 15, and the side wall 16 are the same as those shown in FIGS. 1A to 1C.

Accordingly, the shapes of the high concentration diffusion layers 12d and 12s, the gate electrode 15, and the side wall 16 will be described below.

In an example shown in FIG. 2, an end Ed of the gate electrode 15 in the direction DX includes a region covering the hump suppression diffusion region 32, and an electrode width W1 at the end Ed in the direction DY perpendicular to the direction DX is larger than an electrode width W2 in the region of the gate electrode 15 other than the end Ed in the direction DY. That is, the gate electrode 15 has a configuration in which the center portion thereof is recessed in the direction DY as compared to both ends thereof in the direction DX.

The side wall 16 is formed to cover the side wall of the gate electrode 15 with a substantially uniform film thickness along the side wall as shown in FIG. 2. Accordingly, the contour of the side wall 16 also has a similar shape as that of the contour of the gate electrode 15 as shown in FIG. 2.

Here, as shown in FIG. 2, an interval between the high concentration diffusion layers 12d and 12s in the section P1 in the direction DX in which the hump suppression diffusion region 32 is included between the high concentration diffusion layers 12d and 12s is larger than an interval between the high concentration diffusion layers 12d and 12s in a section P3 other than the section P1. That is, each of the high concentration diffusion layers 12d and 12s has a protrusion portion Pr protruding in the direction of the channel region as shown in FIG. 2 in the section P3 in which the hump suppression diffusion region 32 is not included in the direction DX within the channel region.

In this manner, the section P3 of the high concentration diffusion layers 12d and 12s corresponding to the recessed section of the gate electrode 15 protrudes in the channel direction as shown in FIG. 2 according to a degree by which the electrode width of the gate electrode 15 in the direction DY is recessed in the center portion thereof.

Thereby, the high concentration diffusion layers 12d and 12s become closer to the channel region of the transistor than in a case where the configuration shown in FIG. 1A is adopted, and thus it is possible to increase a current driving capability.

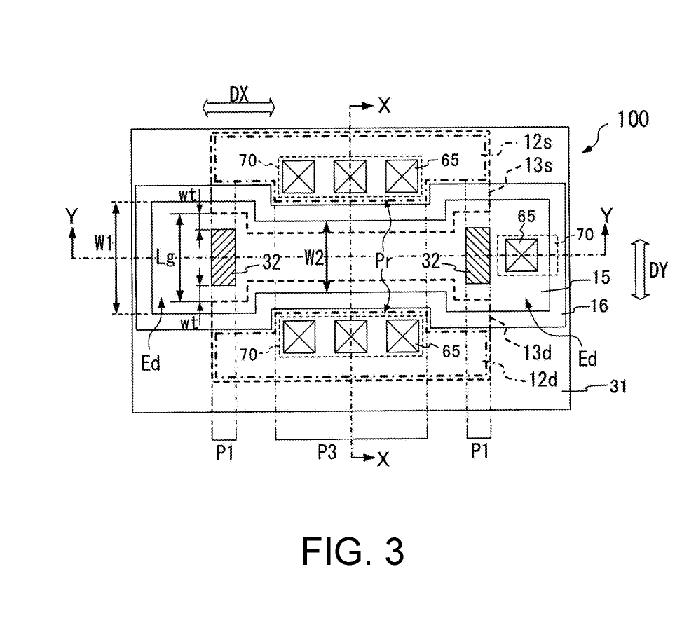

FIG. 3 is a top view when a portion of the semiconductor device 100 according to a modification example of the configuration shown in FIG. 2 is seen from above an element formation surface.

Further, in an example shown in FIG. 3, the contact 65 is coupled to the high concentration diffusion layer 12d (12s) in a region including the protrusion portion Pr of each of the high concentration diffusion layers 12d and 12s, and the other configurations are the same as those shown in FIG. 2.

According to the configuration shown in FIG. 3, a distance between the contact 65 corresponding to a drain electrode (or a source electrode) and the high concentration diffusion layer 12d (12s) interposed between the contact 65 and the gate electrode 15 becomes shorter than in the configuration shown in FIG. 2, and thus it is possible to increase a current driving capability of the transistor.

In short, the semiconductor device 100 may be any semiconductor device as long as the semiconductor device includes a semiconductor substrate on which an element region of a semiconductor and an element isolation region are formed. In the element region, one first diffusion layer, the other first diffusion layer, a gate oxide film, a gate electrode, and a second diffusion layer which is a hump suppression diffusion region, which are to be described below, are formed.

That is, the element isolation region surrounds the element region and includes an insulating film (31) which is in contact with the element region. In addition, one first diffusion layer and the other first diffusion layer (13s, 13d) are formed in an upper portion in the element region so as to extend away from each other in a first direction (DX), and ends thereof in the first direction are in contact with the insulating film (31). The gate oxide film (14) is formed in the element region so as to extend in the first direction, and an end thereof in the first direction is in contact with the insulating film (31). The gate electrode (15) extends in the first direction on the gate oxide film, and an end thereof in the first direction is formed on the insulating film (31). A second diffusion layer (32) is formed in a region including a portion in which the gate oxide film (14) is in contact with the insulating film (31) within a channel region between one first diffusion layer and the other first diffusion layer. Here, an interval (Lg) between one first diffusion layer and the other first diffusion layer in a section (P1) in the first direction in which the second diffusion layer is included between one first diffusion layer and the other first diffusion layer is larger than an interval (CL) between one first diffusion layer and the other first diffusion layer in a section (P2) in the first direction in which the second diffusion layer is not included.

In addition, as the semiconductor device 100, a semiconductor device including a semiconductor substrate, an electrode, a pair of first diffusion layers, and a second diffusion layer, which are to be described below, may be used. That is, a semiconductor substrate (10) includes an element region and an element isolation region (31) surrounding the element region in contact with the element region on its principal surface. The electrode (15) is configured such that an end thereof is disposed on the element isolation region and is disposed on the element region on the above-described principal surface with an insulating layer (14) interposed therebetween. The pair of first diffusion layers (13) are disposed opposite to each other in the element region included in a region corresponding to the electrode (15) when a substrate surface is seen from above the semiconductor substrate in a plan view. The second diffusion layer (32) is formed in contact with a “side” on which a boundary between the element region and the element isolation region is formed and is disposed away from the first diffusion layer (13) in the element region included in the region corresponding to the electrode (15) when seen in a plan view described above. Here, a channel region interposed between the pair of first diffusion layers extends in a direction perpendicular to the above-described “side” and includes the second diffusion layer. The channel region includes a first region (P1) including the second diffusion layer and being configured such that a width in a direction parallel to the “side” is a first length (Lg) and a second region (P2) being configured such that a width in a direction parallel to the “side” is a second length (CL) shorter than the first length.

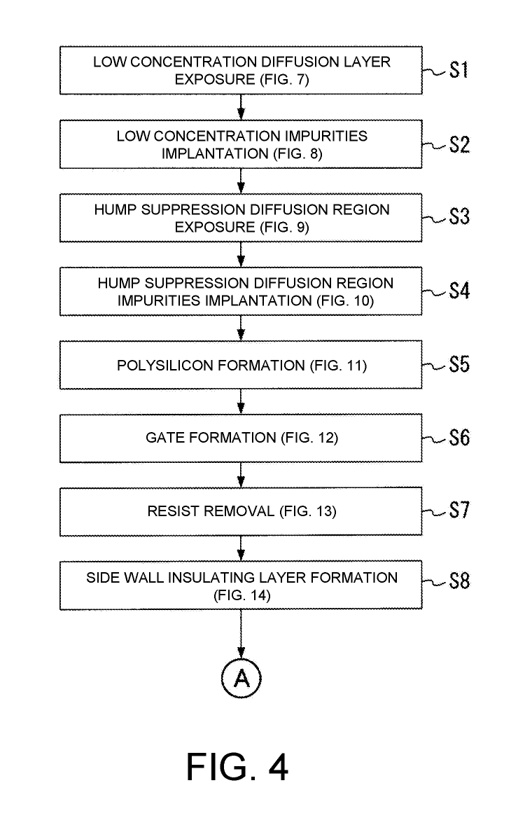

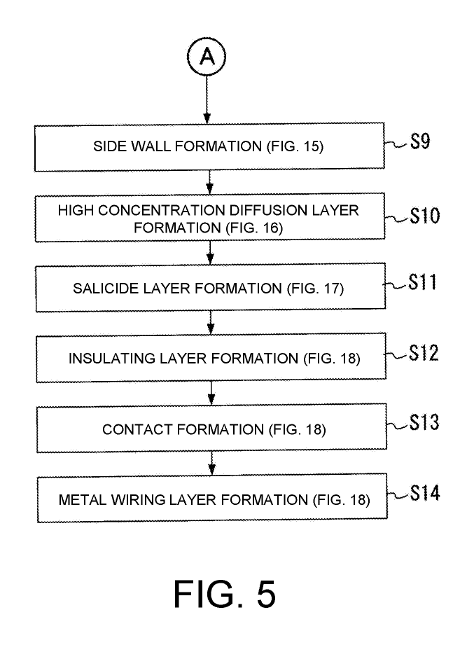

Next, a method of manufacturing the semiconductor device 100 will be described along a manufacturing flow shown in FIGS. 4 and 5.

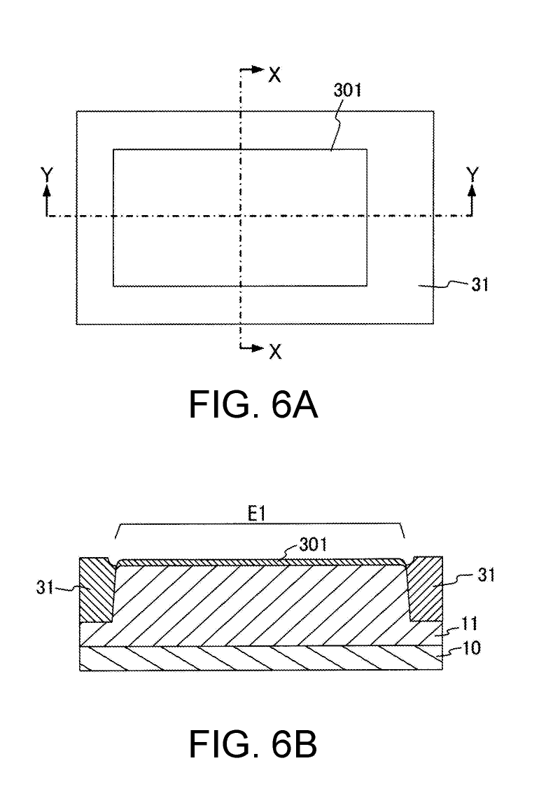

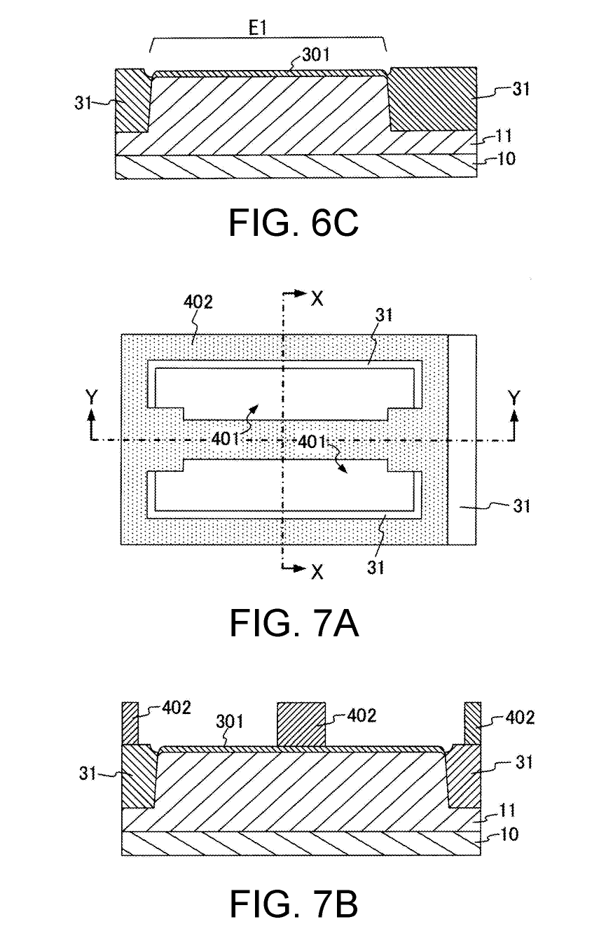

In manufacturing the semiconductor device 100, a semiconductor wafer as shown in FIGS. 6A to 6C is prepared. In addition, FIG. 6A is a top view when a portion of the semiconductor wafer is seen from above the wafer surface. FIG. 6B is a cross-sectional view taken along line X-X in FIG. 6A. In addition, FIG. 6C is a cross-sectional view taken along line Y-Y in FIG. 6A.

As shown in FIGS. 6A to 6C, the wafer includes the semiconductor substrate 10 formed of silicon (Si), the well 11, a thermal oxidation film 301, and the element isolation insulating film 31. That is, the well 11 obtained by thermally diffusing impurities of a p-type conductive type such as boron (B^{t}) is formed on the semiconductor substrate 10. The thermal oxidation film 301 is formed on the surface of an element region E1 on which the transistor is formed, the surface being a principal surface of the semiconductor substrate 10. In addition, the thermal oxidation film 301 is an oxide film obtained by thermally oxidizing the semiconductor substrate 10.

In addition, the vicinity of the element region E1 in the well 11 is configured as an element isolation region. The element isolation region includes a trench annularly surrounding the element region E1 and the element isolation insulating film 31 formed of, for example, a silicon oxide and embedded in the trench.

First, a low concentration diffusion layer exposure step S1 is executed on the wafer shown in FIGS. 6A to 6C.

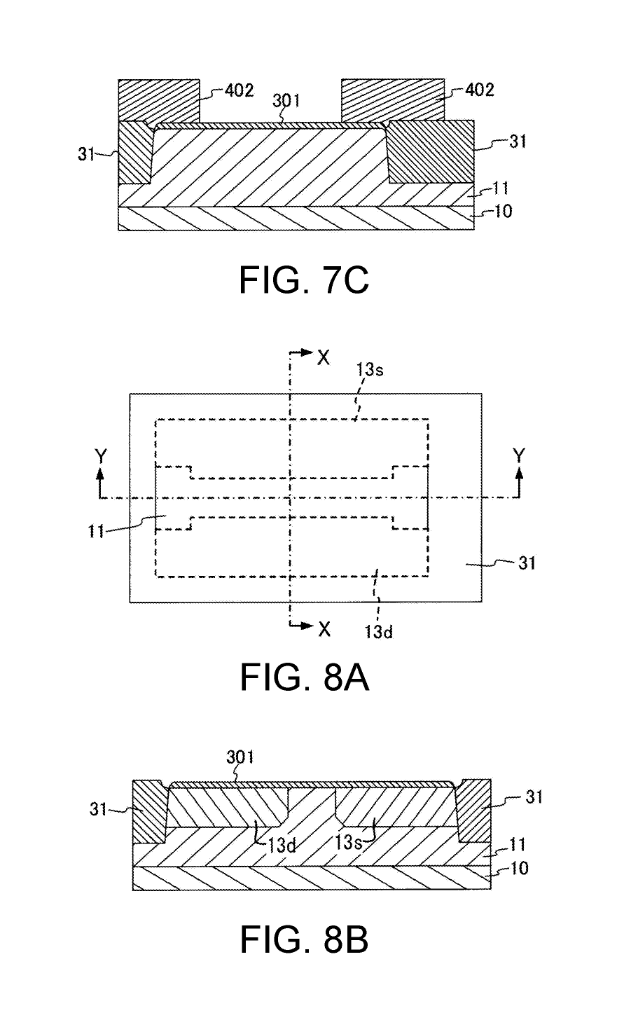

In the low concentration diffusion layer exposure step S1, a resist 402 having an opening 401 exposing a region in which a low concentration diffusion layer is to be formed is formed as shown in FIGS. 7A to 7C. In addition, FIG. 7A is a top view when a portion of the wafer is seen from above the wafer surface. FIG. 7B is a cross-sectional view taken along line X-X in FIG. 7A. FIG. 7C is a cross-sectional view taken along line Y-Y in FIG. 7A.

Next, a low concentration impurity implantation step S2 is executed on the wafer shown in FIGS. 7A to 7C.

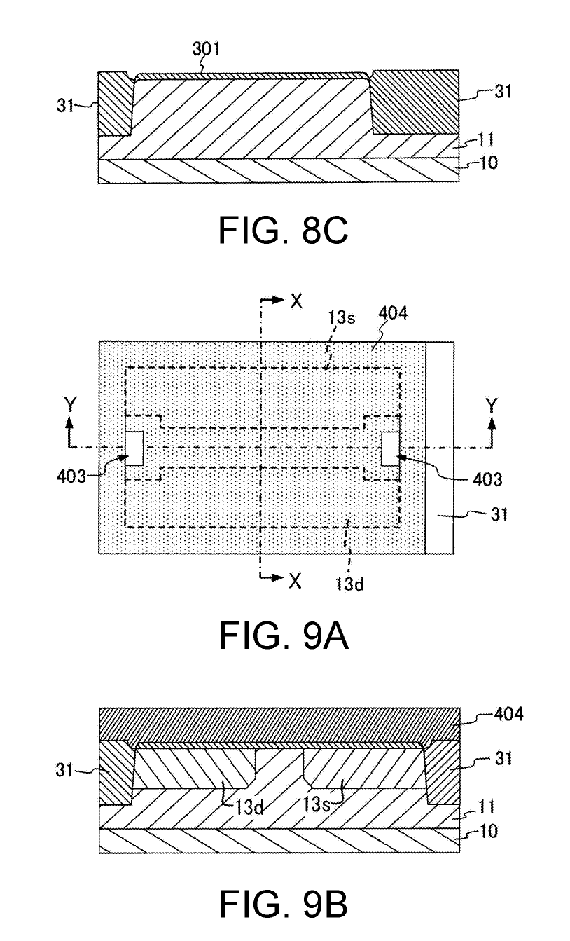

In the low concentration impurity implantation step S2, for example, phosphorus (P⁺) or arsenic (As⁺) as impurities of an n-type conductive type is implanted into the entire region of the wafer surface by an ion implantation device. Thereby, as shown in FIGS. 8A to 8C, the low concentration diffusion layer 13s of an n-type conductive type serving as a source of the transistor and the low concentration diffusion layer 13d of an n-type conductive type serving as a drain of the transistor are formed in the surface layer in the element region E1 corresponding to the opening 401. In addition, FIG. 8A is a top view when a portion of the wafer is seen from above the wafer surface. FIG. 8B is a cross-sectional view taken along line X-X in FIG. 8A. FIG. 8C is a cross-sectional view taken along line Y-Y in FIG. 8A.

That is, the low concentration diffusion layers 13s and 13d having a configuration as shown in FIG. 1A, 2, or 3 are formed through the low concentration impurity implantation step S2.

In the low concentration impurity implantation step S2, the resist 402 is removed as shown in FIGS. 8A to 8C after the low concentration diffusion layers 13s and 13d are formed.

Next, a hump suppression diffusion region exposure step S3 is executed on the wafer shown in FIGS. 8A to 8C.

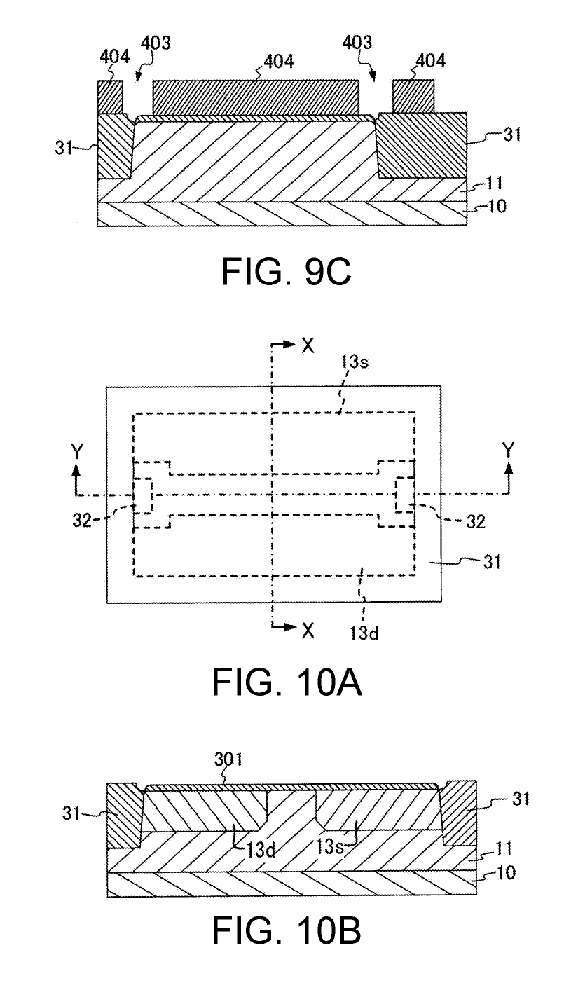

In the hump suppression diffusion region exposure step S3, a resist 404 having an opening 403 exposing a region in which a hump suppression diffusion region is to be formed is formed as shown in FIGS. 9A to 9C. In addition, FIG. 9A is a top view when a portion of the wafer is seen from above the wafer surface. FIG. 9B is a cross-sectional view taken along line X-X in FIG. 9A. FIG. 9C is a cross-sectional view taken along line Y-Y in FIG. 9A.

Next, a hump suppression diffusion region impurity implantation step S4 is executed on the wafer shown in FIGS. 9A to 9C.

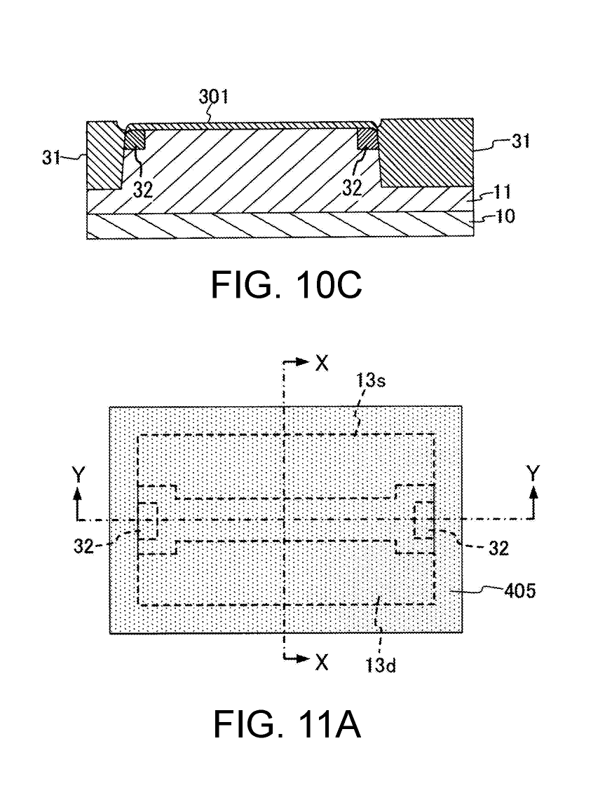

In the hump suppression diffusion region impurity implantation step S4, impurities of a p-type conductive type such as boron (B⁺) as impurities of a p-type conductive type are implanted into the entire region of the wafer surface by an ion implantation device. Thereby, as shown in FIGS. 10A to 10C, the hump suppression diffusion region 32 of a p-type conductive type is formed in the surface layer in the element region E1 corresponding to the opening 403 in which the element isolation insulating film 31 and the thermal oxidation film 301 intersect each other in a region between the low concentration diffusion layer 13d and the low concentration diffusion layer 13s within the well 11. In addition, FIG. 10A is a top view when a portion of the wafer is seen from above the wafer surface. FIG. 10B is a cross-sectional view taken along line X-X in FIG. 10A. FIG. 10C is a cross-sectional view taken along line Y-Y in FIG. 10A.

In a hump suppression diffusion region impurity implantation step S4, the resist 404 is removed as shown in FIGS. 10A to 10C after the hump suppression diffusion region 32 is formed.

Next, a polysilicon formation step S5 is executed on the wafer shown in FIGS. 10A to 10C.

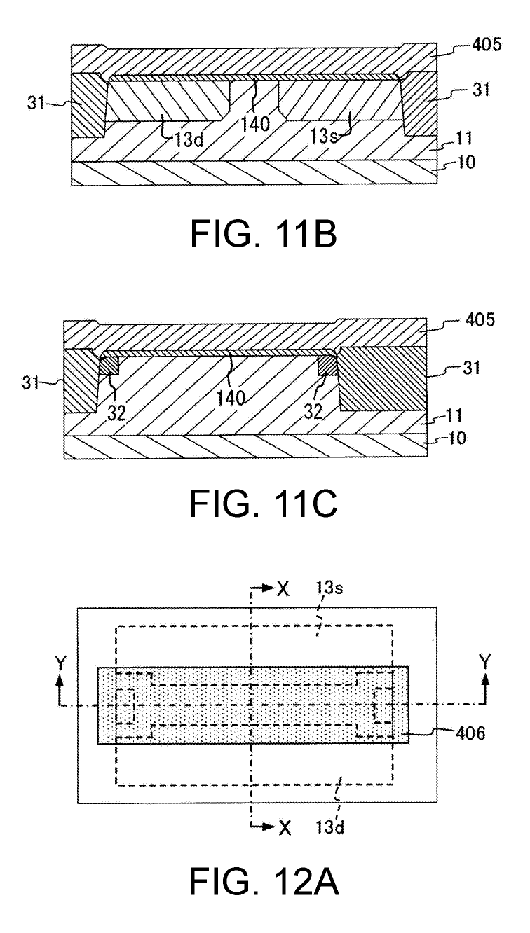

In the polysilicon formation step S5, a gate oxide film 140 is formed on a surface in the element formation region as shown in FIGS. 11B and 11C after the thermal oxidation film 301 is removed. Next, a polysilicon film 405 is formed on the entire top surface of the wafer as shown in FIGS. 11A to 11C by CVD. In addition, FIG. 11A is a top view when a portion of the wafer is seen from above the wafer surface. FIG. 11B is a cross-sectional view taken along line X-X in FIG. 11A. FIG. 11C is a cross-sectional view taken along line Y-Y in FIG. 11A.

Next, a gate formation step S6 is executed on the wafer shown in FIGS. 11A to 11C.

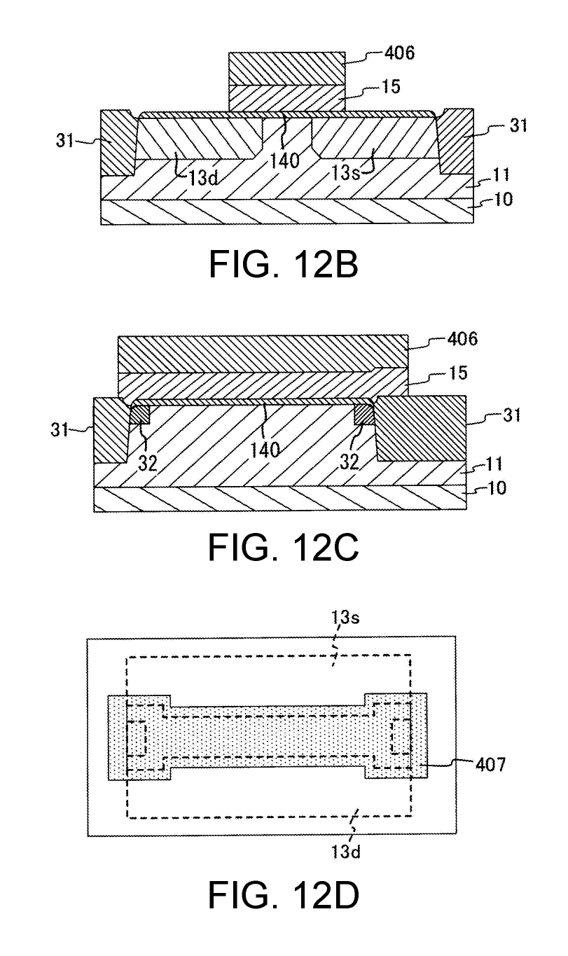

In the gate formation step S6, a resist 406 is formed in a region in which a gate electrode is to be formed, as shown in FIGS. 12A to 12C. In addition, FIG. 12A is a top view when a portion of the wafer is seen from above the wafer surface. FIG. 12B is a cross-sectional view taken along line X-X in FIG. 12A. FIG. 12C is a cross-sectional view taken along line Y-Y in FIG. 12A.

Here, the resist 406 shown in FIG. 12A is a mask for forming the gate electrode 15 shown in FIG. 1A. Further, in a case where the gate electrode 15 having a configuration in which the center portion as shown in FIG. 2 or 3 is recessed in the direction DY is formed, a resist 407 having a configuration shown in FIG. 12D (top view) is formed.

After such a resist 406 or 407 is formed, the gate electrode 15 having a configuration shown in FIG. 1A, 2, or 3 is formed as shown in FIGS. 12A to 12C by dry etching in the gate formation step S6.

Next, a resist removal step S7 is executed on the wafer shown in FIGS. 12A to 12C.

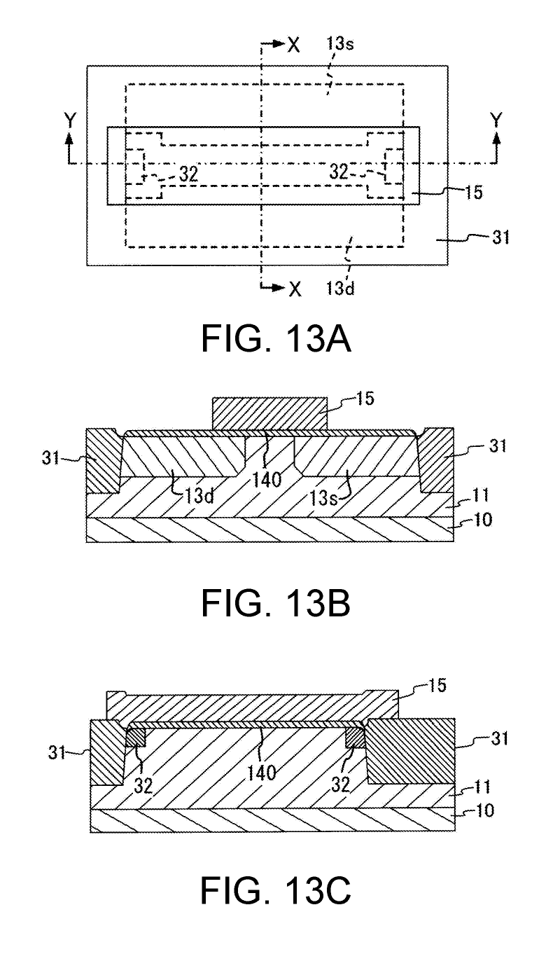

In the resist removal step S7, the resist 406 or 407 formed on the gate electrode 15 is removed as shown in FIGS. 13A to 13C. In addition, FIG. 13A is a top view when a portion of the wafer is seen from above the wafer surface. FIG. 13B is a cross-sectional view taken along line X-X in FIG. 13A. FIG. 13C is a cross-sectional view taken along line Y-Y in FIG. 13A.

Next, a side wall insulating layer formation step S8 is executed on the wafer shown in FIGS. 13A to 13C.

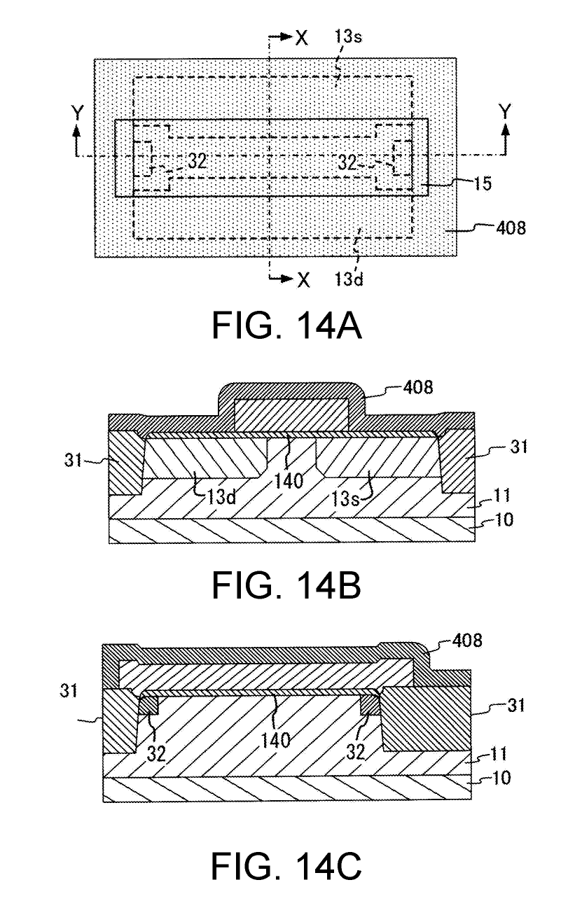

In the side wall insulating layer formation step S8, an insulating layer 408 containing a silicon oxide is formed on the entire region of the wafer surface as shown in FIGS. 14A to 14C, for example, through plasma processing based on CVD. In addition, FIG. 14A is a top view when a portion of the wafer is seen from above the wafer surface. FIG. 14B is a cross-sectional view taken along line X-X in FIG. 14A. FIG. 14C is a cross-sectional view taken along line Y-Y in FIG. 14A.

Next, a side wall formation step S9 is executed on the wafer shown in FIGS. 14A to 14C.

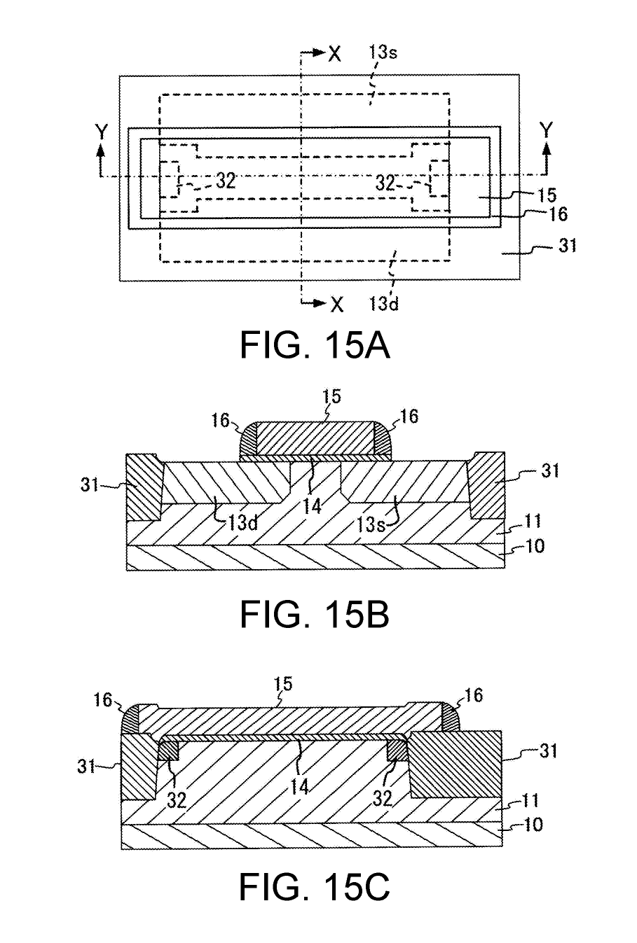

In the side wall formation step S9, the entire surface of the wafer shown in FIGS. 14A to 14C is etched through anisotropic dry etching. Thereby, as shown in FIGS. 15A to 15C, the side wall 16 based on the insulating layer 408 is formed on the side wall of the gate electrode 15. In addition, FIG. 15A is a top view when a portion of the wafer is seen from above the wafer surface. FIG. 15B is a cross-sectional view taken along line X-X in FIG. 15A. FIG. 15C is a cross-sectional view taken along line Y-Y in FIG. 15A.

Further, according to the etching performed on the entire surface of the wafer through the above-described anisotropic dry etching, the gate oxide film 140 is removed except for a region masked by the gate electrode 15 and side wall 16 in the gate oxide film 140.

Next, a high concentration diffusion layer formation step S10 is executed on the wafer shown in FIGS. 15A to 15C.

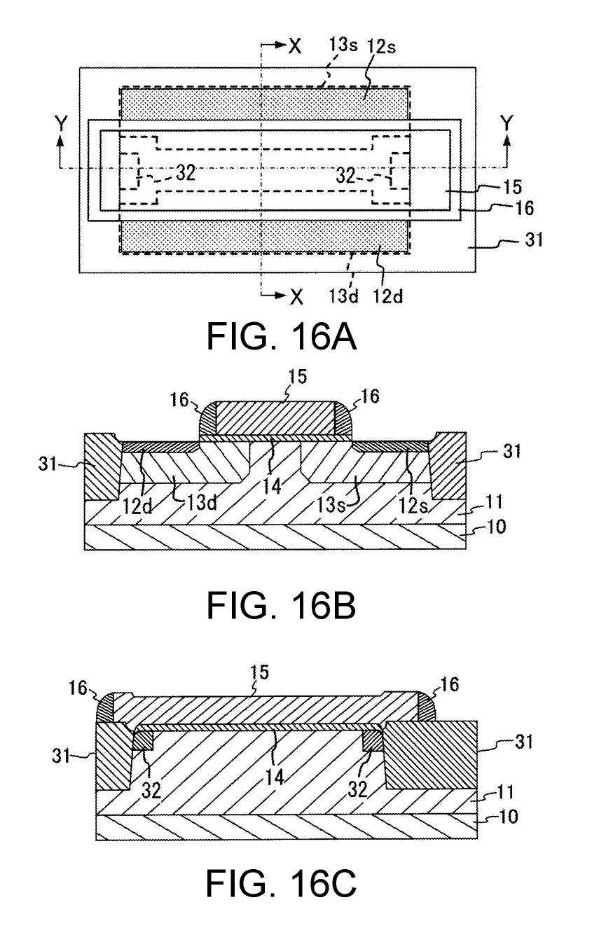

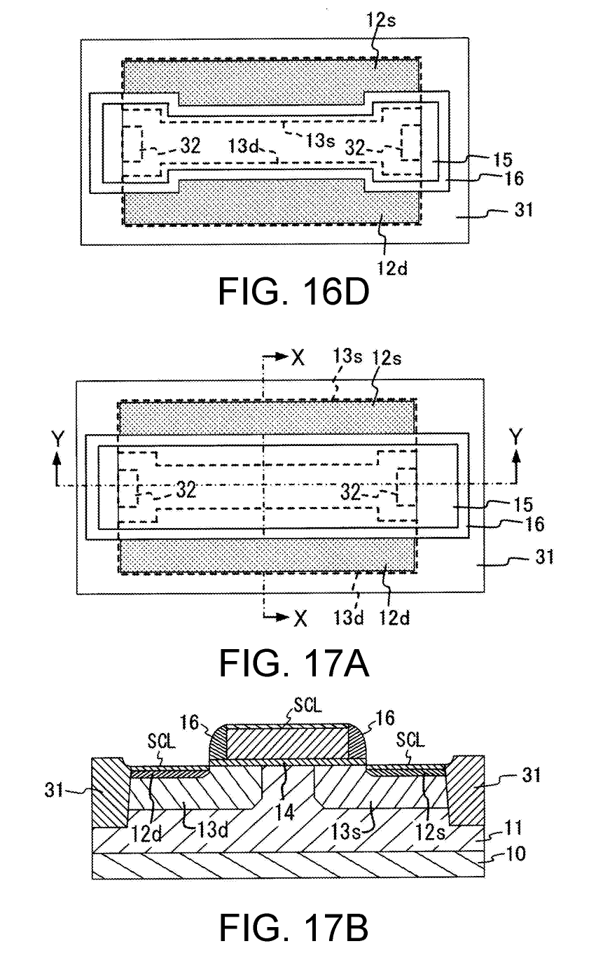

In the high concentration diffusion layer formation step S10, for example, P³⁺(phosphorus) or As⁺(arsenic) as impurities of an n-type conductive type is implanted into the surface layers of the low concentration diffusion layers 13d and 13s by an ion implantation device using the gate electrode 15 and the side wall 16 as masks. Thereby, as shown in FIGS. 16A to 16C, in the region of the surface layers of the low concentration diffusion layers 13d and 13s, impurity concentration in a region which is not masked by the gate electrode 15 and the side wall 16 is increased, and the region is formed as high concentration diffusion layers 12s and 12d. In addition, FIG. 16A is a top view when a portion of the wafer is seen from above the wafer surface. FIG. 16B is a cross-sectional view taken along line X-X in FIG. 16A. FIG. 16C is a cross-sectional view taken along line Y-Y in FIG. 16A.

Here, the high concentration diffusion layers 12s and 12d shown in FIG. 16A are layers formed by using the gate electrode 15 and the side wall 16 having a rectangular shape shown in FIG. 1A as masks. On the other hand, in a case where the gate electrode 15 and the side wall 16 having a configuration shown in FIG. 2 or 3 are used as masks, the high concentration diffusion layers 12s and 12d having a protrusion portion protruding in the channel direction in a recessed section in which the electrode width of the gate electrode 15 decreases are formed as shown in FIG. 16D (top view).

Next, a salicide layer formation step S11 is executed on the wafer shown in FIGS. 16A to 16D.

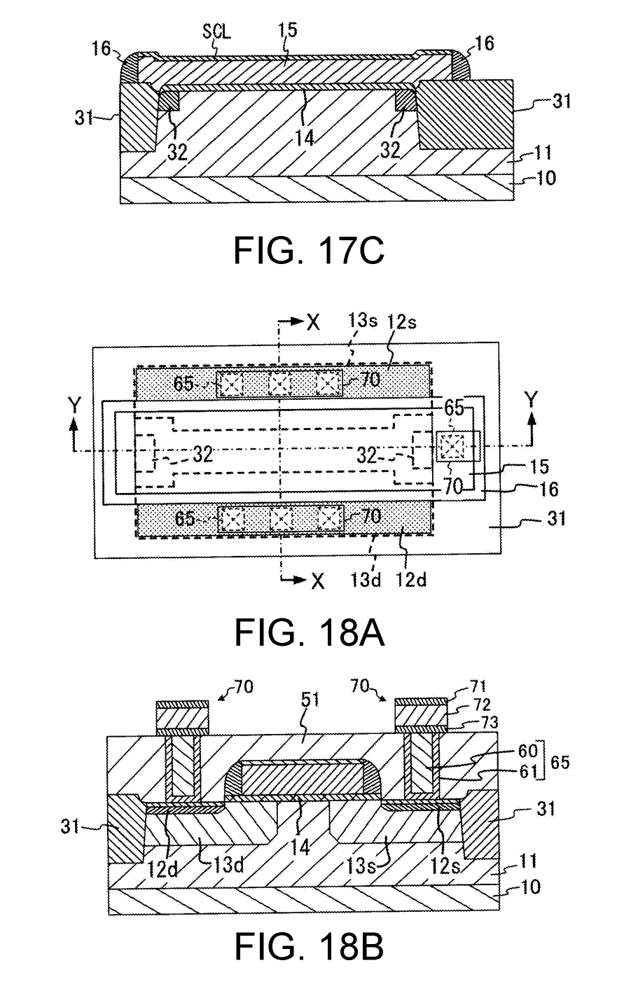

In the salicide layer formation step S11, first, a region in which a salicide layer is to be formed, that is, an insulating layer having an opening in the top surface of each of the gate electrode 15 and the high concentration diffusion layers 12d and 12s is formed on the surface of the wafer shown in FIGS. 16A to 16D. Next, a metal such as cobalt (Co) is sputtered on the entire surface of the wafer by a sputtering device. In addition, a salicide layer SCL obtained by siliciding the top face of each of the gate electrode 15 and the high concentration diffusion layers 12d and 12s is formed as shown in FIGS. 17A to 17C by performing annealing and then removing unreacted cobalt remaining on the surface of the wafer. In addition, FIG. 17A is a top view when a portion of the wafer is seen from above the wafer surface. FIG. 17B is a cross-sectional view taken along line X-X in FIG. 17A. FIG. 17C is a cross-sectional view taken along line Y-Y in FIG. 17A.

Next, an insulating layer formation step S12 is executed on the wafer shown in FIGS. 17A to 17C.

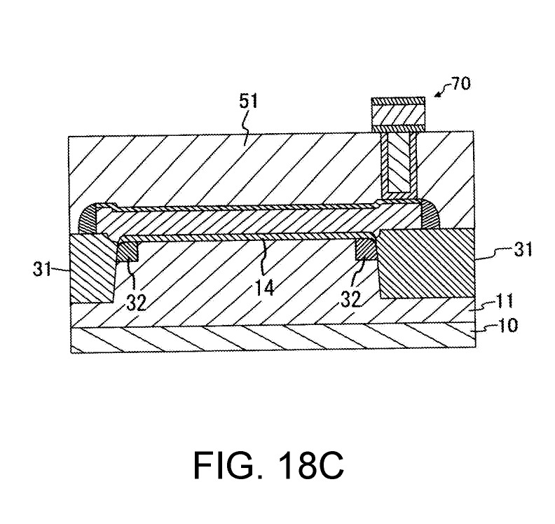

In the insulating layer formation step S12, first, the insulating layer 51 constituted by an undoped plasma oxide film such as a non-doped silicate glass (NSG) film is formed on the entire surface of the wafer as shown in FIGS. 18A to 18C on the basis of a CVD method. In addition, FIG. 18A is a top view when a portion of the wafer is seen from above the wafer surface. FIG. 18B is a cross-sectional view taken along line X-X in FIG. 18A. FIG. 18C is a cross-sectional view taken along line Y-Y in FIG. 18A.

Further, in the insulating layer formation step S12, the top face of the insulating layer 51 is smoothened by polishing using chemical mechanical polishing (CMP).

Next, a contact formation step S13 is executed on the wafer shown in FIGS. 17A to 17C.

In the contact formation step S13, first, dry etching is performed on the insulating layer 51 by using a resist covering regions other than the region of the contact 65 on the top face of the insulating layer 51 as a mask. Thereby, contact holes exposing the gate electrode 15 and the high concentration diffusion layers 12d and 12s are formed. Next, in the contact formation step S13, a barrier metal such as titanium nitride (TiN) is formed on the entire region of the surface of the wafer. Thereby, the barrier metal 61 is formed in each of the contact holes as shown in FIGS. 18A to 18C. Next, for example, tungsten which is a high melting point metal is formed on the entire region of the surface of the wafer. Thereby, tungsten is embedded in the contact hole, and the metal plug 60 covered with the barrier metal 61 is formed in the contact hole as shown in FIGS. 18A to 18C. Thereafter, tungsten and titanium formed on the top face of the insulating layer 51 are removed by polishing using CMP or by wet etching.

Next, a metal wiring layer formation step S14 is executed.

In the metal wiring layer formation step S14, first, the lower layer barrier metal 73, the conductive member 72, and the upper layer barrier metal layer 71 are stacked on the top face of the insulating layer 51 by sputtering. The lower layer barrier metal 73 is formed of, for example, titanium (Ti), titanium nitride (TiN), or the like, and the conductive member 72 is formed of an alloy such as aluminum-copper (Al—Cu). Next, in the metal wiring layer formation step S14, the upper layer barrier metal layer 71, the conductive member 72, and the lower layer barrier metal 73 are etched by masking a region equivalent to a metal wiring on the top face of the barrier metal layer 71 by a resist. Thereby, as shown in FIGS. 18A to 18C, the metal wiring layer 70 having a stacked structure constituted by the upper layer barrier metal layer 71, the conductive member 72, and the lower layer barrier metal 73 is formed on the top face of the insulating layer 51.

In short, any method may be used as a method of manufacturing the semiconductor device 100 including an element region (11) of a semiconductor and an element isolation region (E1) which surrounds the element region and includes an insulating film (31) which is in contact with the element region as long as the method includes the following first to third steps.

In the first step (S1, S2), one first diffusion layer and the other first diffusion layer (13d, 13s) are formed by implanting impurities into an upper portion in the element region such that the diffusion layers extend away from each other in a first direction (DX) and ends thereof in the first direction are in contact with the insulating film (31). In the second step (S3, S4), a second diffusion layer (32) which is a hump suppression diffusion region is formed by implanting impurities into a region including a portion which is in contact with the insulating film in an upper portion of a channel region interposed between one first diffusion layer and the other first diffusion layer. In the third step (S5, S6), a gate oxide film (14, 140) extending in the first direction on the element region is formed such that an end thereof in the first direction is in contact with the insulating film. Further, in the third step, a gate electrode (15) extending in the first direction on the gate oxide film is formed such that an end thereof in the first direction is on the insulating film. Further, in the first step, one first diffusion layer and the other first diffusion layer are formed in an upper portion in the element region such that an interval (Lg) between one first diffusion layer and the other first diffusion layer in a section (P1) in the first direction in which the second diffusion layer is included between one first diffusion layer and the other first diffusion layer becomes larger than an interval (CL) between one first diffusion layer and the other first diffusion layer in a section (P2 or P3) in the first direction in which the second diffusion layer is not included.

### REFERENCE SIGNS LIST

11 Well
12d, 12s High concentration diffusion layer
13d, 13s Low concentration diffusion layer
15 Gate electrode
16 Side wall
31 Element isolation insulating film
32 Hump suppression diffusion region
100 Semiconductor device

What is claimed is:

1. A semiconductor device comprising:
a semiconductor substrate on which an element region of a semiconductor and an element isolation region surrounding the element region and including an insulating film which is in contact with the element region are formed;
one first diffusion layer and another first diffusion layer which are formed in an upper portion in the element region to extend away from each other in a first direction and are configured such that ends thereof in the first direction are in contact with the insulating film;
a gate oxide film which is formed on the element region to extend in the first direction and is configured such that an end thereof in the first direction is in contact with the insulating film;
a gate electrode which extends in the first direction on the gate oxide film and is configured such that an end thereof in the first direction is formed on the insulating film; and
a second diffusion layer which is formed in a region including a portion in which the gate oxide film is in contact with the insulating film within a channel region between the one first diffusion layer and the other first diffusion layer,
wherein an interval between the one first diffusion layer and the other first diffusion layer in a section in the first direction in which the second diffusion layer is included between the one first diffusion layer and the other first diffusion layer is larger than an interval between the one first diffusion layer and the other first diffusion layer in a section in the first direction in which the second diffusion layer is not included.

2. The semiconductor device according to claim 1, wherein the insulating film is embedded in a trench formed in the semiconductor substrate.

3. The semiconductor device according to claim 1, wherein the second diffusion layer contains impurities having a higher concentration than those of the channel region.

4. The semiconductor device according to claim 1, wherein the second diffusion layer and the channel region are of a first conductive type, and the one first diffusion layer and the other first diffusion layer are of a second conductive type different from the first conductive type.

5. The semiconductor device according to claim 1, wherein
one high concentration diffusion layer and another high concentration diffusion layer which contain impurities having a higher concentration than those of the one first diffusion layer and the other first diffusion layer are formed in a surface layer of each of the one first diffusion layer and the other first diffusion layer,
the end of the gate electrode includes a region covering the second diffusion layer, and an electrode width in a direction perpendicular to the first direction at the end of the gate electrode is larger than an electrode width in the direction perpendicular to the first direction in a region of the gate electrode other than the end, and
an interval between the one high concentration diffusion layer and the other high concentration diffusion layer in a section in the first direction in which the second diffusion layer is included between the one high concentration diffusion layer and the other high concentration diffusion layer is larger than an interval between the one high concentration diffusion layer and the other high concentration diffusion layer in a section in the first direction in which the second diffusion layer is not included.

6. The semiconductor device according to claim 5, wherein
each of the one high concentration diffusion layer and the other high concentration diffusion layer includes a protrusion portion protruding in a direction of the channel region in the section in the first direction in which the second diffusion layer is not included between the one high concentration diffusion layer and the other high concentration diffusion layer, and
a contact is coupled to a region including the protrusion portion on the top face of each of the one high concentration diffusion layer and the other high concentration diffusion layer.

7. A semiconductor device comprising:
a semiconductor substrate which includes an element region and an element isolation region surrounding the element region in contact with the element region on a principal surface thereof;
an electrode which is configured such that an end thereof is disposed on the element isolation region and is disposed in the element region on the principal surface with an insulating layer interposed therebetween;
a pair of first diffusion layers which are disposed opposite to each other in the element region included in a region corresponding to the electrode when seen in a plan view; and
a second diffusion layer which is in contact with a side on which a boundary between the element region and the element isolation region is formed and is disposed away from the pair of first diffusion layers in the element region included in the region corresponding to the electrode when seen in a plan view,
wherein a channel region interposed between the pair of first diffusion layers extends in a direction perpendicular to the side and includes the first diffusion layers, and
the channel region includes a first region including the second diffusion layer and configured such that a width in a direction parallel to the side is a first length, and a second region configured such that a width in a direction parallel to the side is a second length shorter than the first length.

8. A method of manufacturing a semiconductor device that includes an element region of a semiconductor and an element isolation region surrounding the element region and including an insulating film which is in contact with the element region, the method comprising:
a first step of implanting impurities into an upper portion in the element region to form one first diffusion layer and another first diffusion layer which extend away from each other in a first direction and are configured such that ends thereof in the first direction are in contact with the insulating film;
a second step of implanting impurities into a region including a portion which is in contact with the insulating film in an upper portion in a channel region interposed between the one first diffusion layer and the other first diffusion layer to form a second diffusion layer; and
a third step of forming a gate oxide film which extends in the first direction on the element region and is configured such that an end thereof in the first direction is in contact with the insulating film, and a gate electrode which extends in the first direction on the gate oxide film and is configured such that an end thereof in the first direction is disposed on the insulating film,
wherein the first step includes forming the one first diffusion layer and the other first diffusion layer in the upper portion in the element region, the first diffusion layers being configured such that an interval between the one first diffusion layer and the other first diffusion layer in a section in the first direction in which the second diffusion layer is included between the one first diffusion layer and the other first diffusion layer becomes larger than an interval between the one first diffusion layer and the other first diffusion layer in a section in the first direction in which the second diffusion layer is not included.

9. The method according to claim 8, wherein the insulating film is embedded in a trench formed in the semiconductor substrate.

10. The method according to claim 8, wherein the second step includes forming the second diffusion layer by implanting impurities having a higher concentration than those of the one first diffusion layer and the other first diffusion layer into the element region.

11. The method according to claim 8, wherein
the element region is of a first conductive type,
the first step includes forming the one first diffusion layer and the other first diffusion layer by implanting impurities of a second conductive type different from the first conductive type into the element region, and
the second step includes forming the second diffusion layer by implanting impurities of the first conductive type into the element region.

12. The method according to claim 8, further comprising:
a fourth step of forming one high concentration diffusion layer and another high concentration diffusion layer in a surface layer of each of the one first diffusion layer and the other first diffusion layer by implanting impurities having a higher concentration than those of the one first diffusion layer and the other first diffusion layer into the one first diffusion layer and the other first diffusion layer,
wherein the third step includes forming the gate electrode configured such that an electrode width in a direction perpendicular to the first direction at the end including a region covering the second diffusion layer in the gate electrode becomes larger than an electrode width in a direction perpendicular to the first direction in a region of the gate electrode other than the end, and
the fourth step includes forming the one high concentration diffusion layer and the other high concentration diffusion layer on top faces of the one first diffusion layer and the other first diffusion layer, the high concentration diffusion layers being configured such that an interval between the one high concentration diffusion layer and the other high concentration diffusion layer in a section in the first direction in which the second diffusion layer is included between the one high concentration diffusion layer and the other high concentration diffusion layer becomes larger than an interval between the one high concentration diffusion layer and the other high concentration diffusion layer in a section in the first direction in which the second diffusion layer is not included.

13. The method according to claim 12, wherein
the fourth step includes forming the one high concentration diffusion layer and the other high concentration diffusion layer each of which includes a protrusion portion protruding in a direction of the channel region in the section in the first direction in which the second diffusion layer is not included within the channel region, and
the method further comprises a fifth step of forming a contact coupled to a region including the protrusion portion of each of the one high concentration diffusion layer and the other high concentration diffusion layer.
